(19) United States
(12) Patent Application Publication
(10) Pub. No.: US 2015/0156900 A1
(43) Pub. Date: Jun. 4, 2015

(54) CASE FOR PORTABLE ELECTRONIC DEVICE

(71) Applicant: HON HAI PRECISION INDUSTRY CO., LTD., New Taipei (TW)

(72) Inventors: GUO-LIANG YEH, New Taipei (TW); TZU-CHENG YU, Santa Clara, CA (US); PO-CHING HUANG, New Taipei (TW)

(21) Appl. No.: 14/533,273

(22) Filed: Nov. 5, 2014

(30) Foreign Application Priority Data
Nov. 30, 2013 (CN) 201310622015.7

(51) Int. Cl. H05K 5/02; H05K 5/03

(52) U.S. Cl. CPC H05K 5/0217; H05K 5/03

(57) ABSTRACT

A case is for receiving and protecting a portable electronic device, the case includes a main body, a peripheral component and a plurality of fastening pieces. The main body includes a base and a plurality of fastening portions formed on the base on one side, the base includes a receiving space on the opposite side for receiving the portable electronic device. The peripheral component defines a plurality of engaging holes. The fastening pieces are inserted through the plurality of engaging holes and engage the fastening portions, thereby fastening the peripheral component to the main body.

### FIELD

The present disclosure relates to a case for portable electronic devices, and particularly relates to a case for coupling peripheral components.

### BACKGROUND

Portable electronic devices, such as mobile phones and tablet computers, may need cases for protection. Therefore, the case can strengthen the portable electronic device. However, a single case only has a simplex structure, color, and design. Thus, the case needs more transformable in colors, appearances, and patterns.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an exploded view of an exemplary embodiment of a case for a portable electronic device.

FIG. 2 is an isometric view of a main body of the case of FIG. 1.

FIG. 3 is another isometric view of the main body of the case of FIG. 1.

FIG. 4 is an isometric view of a peripheral component of the case of FIG. 1.

FIG. 5 is an assembled isometric view of the case of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

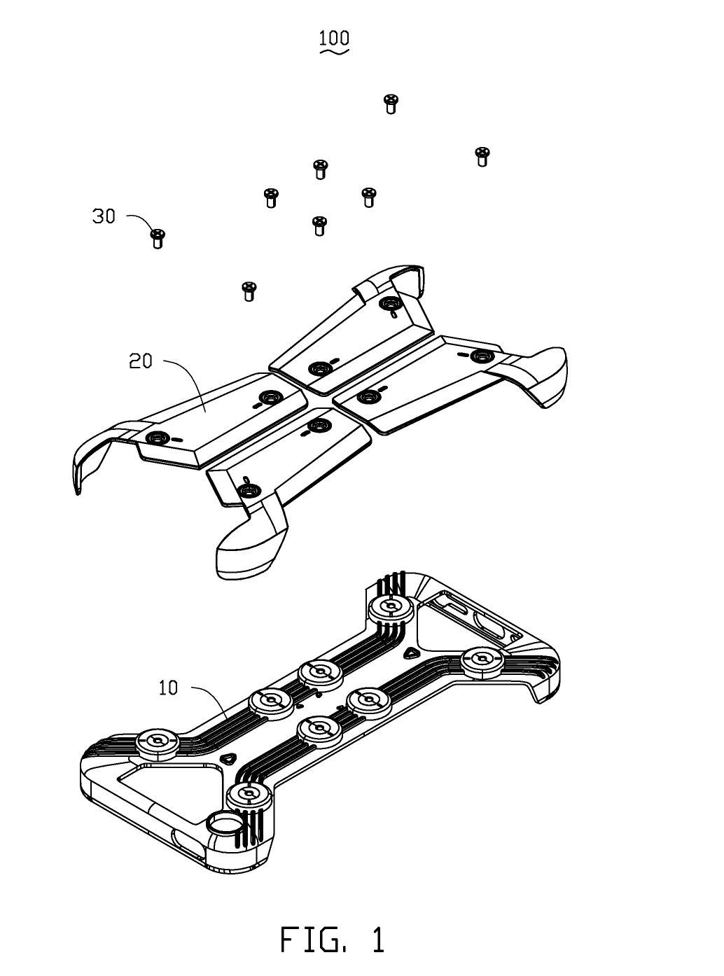

FIG. 1 illustrates an exemplary embodiment of a case 100 for a portable electronic device. The case 100 includes a main body 10, a peripheral component 20, and a plurality of fasten pieces 30. The peripheral component 20 is coupled to the main body 10 via the fasten pieces 30.

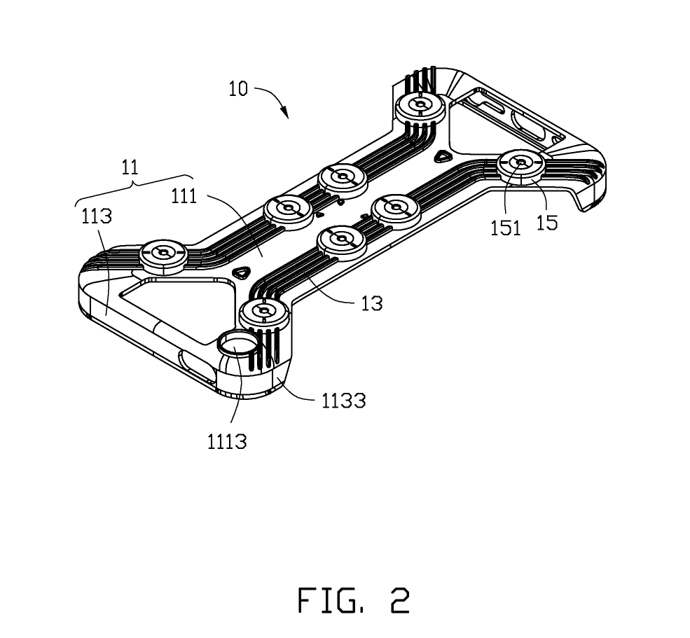

Referring to FIG. 2, the main body 10 includes a base 11, a plurality of flanges 13, and a plurality of fastening portions 15. The flanges 13 are formed on the base 11 and include two groups, the flanges 13 in each group are substantially parallel to each other. The fastening portions 15 are formed through the flanges 13 and the bases 11. The fastening portions 15 divide the flanges 13 into several sections. In one embodiment, each fastening portion 15 is formed with a nut, the base 11 and the flanges 13 are made of plastic material. The fastening portions 15 are formed in the flanges 13 and the bases 11 via injection molding.

In other embodiments, the flanges 13 can be adhered to the base 11 via adhesive dispensing.

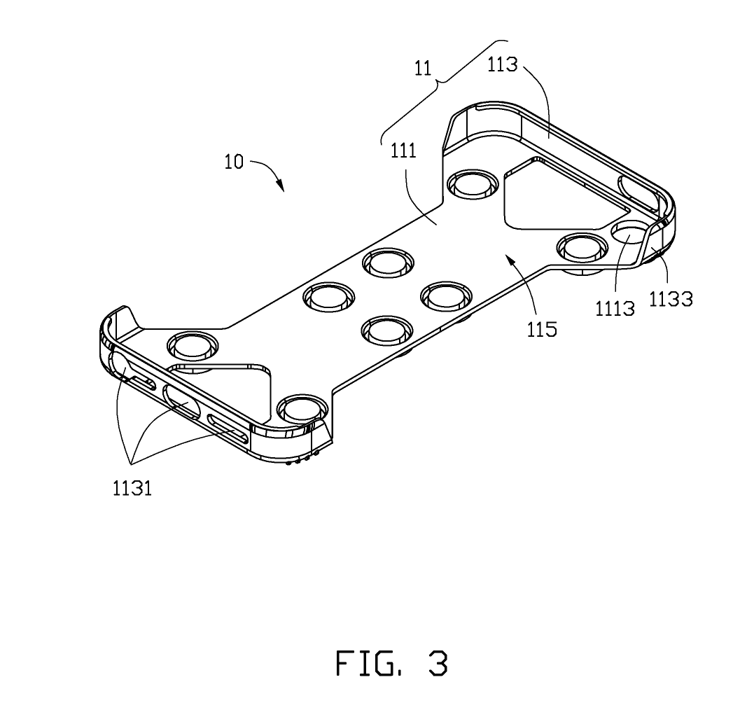

Referring to FIGS. 2 and 3, the base 11 includes a bottom wall 111 and at least two opposite side walls 113. The bottom wall 111 and the at least two side walls cooperatively 113 enclose a receiving space 115 for receiving the portable electronic device. The bottom wall 111 defines a bottom hole 1113 for disposing a camera and/or a LED light of the portable electronic device. The two side walls 113 define a plurality of side holes 1131 for disposing interfaces of the portable electronic device, such as a power button, an earphone jack, a data connector, a speaker and etc. Two opposite ends of each side wall 113 extends towards the bottom wall 111 to form two resisting walls 1133 for securing the portable electronic device in the receiving space 115.

The flanges 13 are formed on an external surface of the bottom wall 111 and are extended from one end of the bottom wall 111 to another end. The flanges 13 strengthen the base 11 and increase a friction between the base 11 and a user.

Each fastening portion 15 defines a fastening hole 151 for engaging with the fasten piece 30.

The flanges 13 and the fastening portions 15 can be operated with some surface preparation, such as scrub processing, spraying treatment, or electroplating treatment, to make the surface with different colors, glossy, and texture, therefore increasing visual sense, strength, and friction.

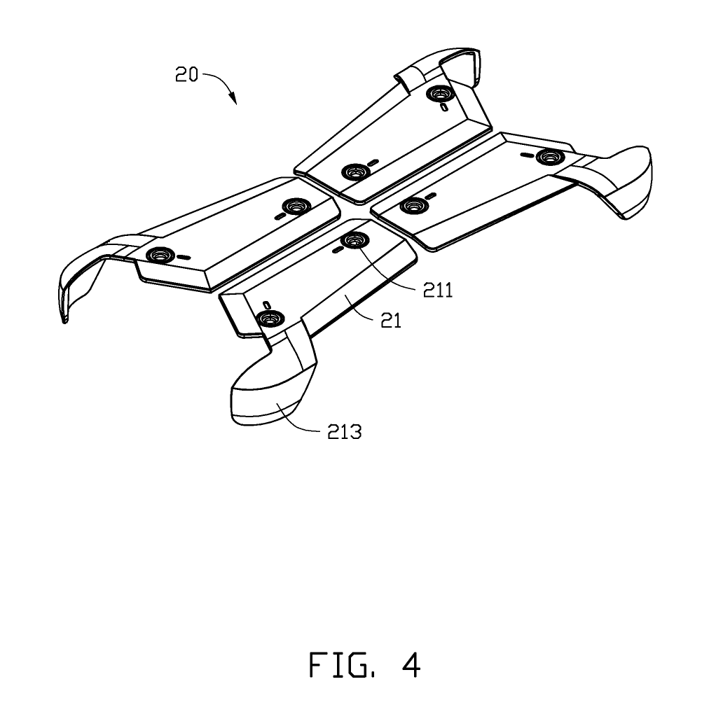

Referring to FIG. 4, the peripheral component 20 includes four cover pieces 21 in a same size. Each cover piece 21 defines two engaging holes 211 on two ends. The engaging holes 211 are for engaging with the fastening portion 15 to couple the cover pieces 21 to the base 11. Each cover piece 21 forms a latching portion 213 on one end by extending outwardly, the latching portion 213 is for latching to the base 11, and therefore strengthening the base 11.

In other embodiments, the peripheral component 20 can be made of metal or a mixture material of metal and plastic. The peripheral component 20 can further include some functional modules, such as a camera module or a flash module.

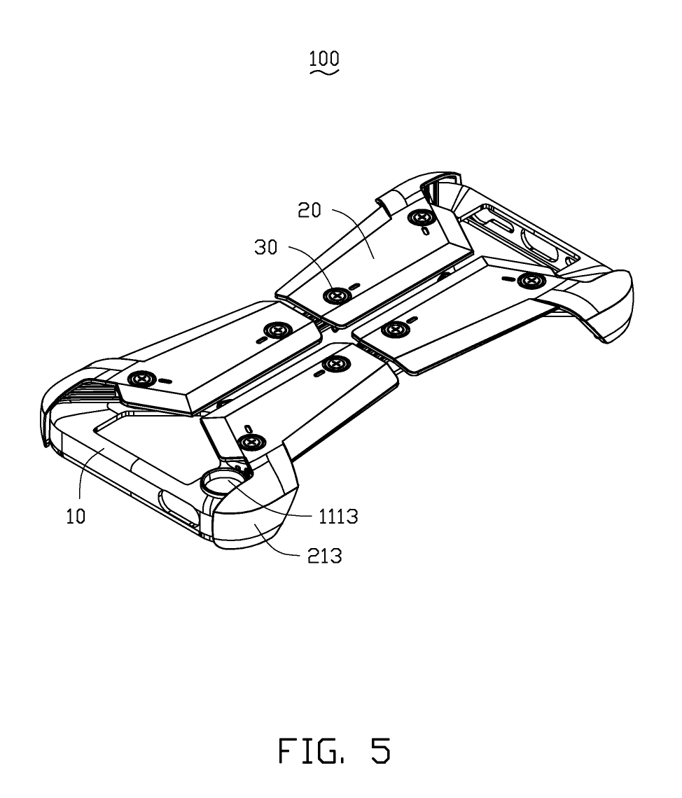

Referring to FIG. 5, the peripheral component 20 coupled to the main body 20 can be operated as follows: each cover piece 21 is mounted on the base 11, the latching portion 213 latches to the corresponding resisting wall 1133, the engaging holes 211 are aligned with the fasting portions 15. The fasten pieces 30 are inserted through the engaging holes 211 and the fastening holes 151 to fasten the cover pieces 21 on the base 11.

When using the case 100, the receiving space 115 can receive a portable electronic device, and the resisting walls 1133 latch edges of the portable electronic device. The bottom hole 1113 and the side holes 1131 dispose camera and interfaces of the portable electronic device. The cover pieces 21 can be made of different material and colors, when different cover pieces 21 are coupled to the base 11, the case 100 has different appearances and touching feelings. To change the peripheral component 20, the user can loosen the fastening pieces 30 from the main body 10 and the component 20, and replace with different peripheral components 20 to the main body 10, which is very convenient for changing different appearances and touching feelings for the case 100.

The case 100 includes a plurality of flanges 13 arranged on the base 11 to strengthen the case 100 and to increase a friction between the user's hand and the case 100 when the case 100 without the peripheral components 20. Users can further change different peripheral components 20 to the main body 10 via the fastening portion 15 and the fasten pieces 30, thereby providing different appearances textures.

It is believed that the embodiments and their advantages will be understood from the foregoing description, and it will be apparent that various changes may be made thereto without departing from the scope of the disclosure or sacrificing all of its advantages, the examples hereinbefore described merely being illustrative embodiments of the disclosure.

What is claimed is:

1. A case for receiving and protecting a portable electronic device, the case comprising:
a main body comprising a base and a plurality of fastening portions formed on the base on one side, the base comprising a receiving space on the opposite side for receiving the portable electronic device;
a peripheral component defining a plurality of engaging holes; and
a plurality of fastening pieces;
wherein the fastening pieces are inserted through the plurality of engaging holes and engage the fastening portions, thereby fastening the peripheral component to the main body.

2. The case as claimed in claim 1, wherein each fastening portion defines a fastening hole, the fastening hole is aligned with the engaging hole, the fastening piece is fastened with the fastening hole.

3. The case as claimed in claim 1, wherein the base comprises a bottom wall and at least two opposite side walls, the at least two side walls are on opposite ends of the bottom wall, the fastening portions are arranged on the bottom wall, each side wall comprises two resisting wall extended towards the bottom wall.

4. The case as claimed in claim 3, wherein the main body further comprises a plurality of flanges, the flanges are formed on the base and divided into two groups, the flanges in each group are substantially parallel to each other, the fastening portions are arranged between the flanges and divide the flanges into several sections.

5. The case as claimed in claim 4, wherein the flanges are extended from one end of the bottom wall to the other end.

6. The case as claimed in claim 3, wherein the peripheral component comprises a plurality of cover pieces, each cover piece comprises a latching portion extended outwardly, each latching portion latches to the resisting wall.

7. The case as claimed in claim 3, wherein the bottom wall defines a bottom hole and the side walls define a plurality of side holes, the bottom hole and the side holes dispose some portions of the portable electronic device.

8. The case as claimed in claim 1, wherein the peripheral component is made of metal, plastic, or a mixture material of metal and plastic.

9. A case for receiving and protecting a portable electronic device, the case comprising:
a main body comprising a base and a plurality of fastening portions formed on the base on one side, the base comprising a receiving space on the opposite side for receiving the portable electronic device; and
a peripheral component comprising a plurality of cover pieces;
wherein the peripheral component are coupled to the base, and the base changes different cover pieces via the fastening portions.

10. The case as claimed in claim 9, wherein each fastening portion defines a fastening hole, each cover piece defines two engaging holes on opposite ends, each fastening hole is aligned with one corresponding engaging hole.

11. The case as claimed in claim 10, further comprising a plurality of fastening pieces, wherein the fastening pieces are inserted through the engaging holes and fastened with the fastening holes, thereby fastening the cover pieces to the main body.

12. The case as claimed in claim 9, wherein the base comprises a bottom wall and at least two opposite side walls, the at least two side walls are on opposite ends of the bottom wall, the fastening portions are arranged on the bottom wall, each side wall comprises two resisting wall extended towards the bottom wall.

13. The case as claimed in claim 12, wherein the main body further comprises a plurality of flanges, the flanges are formed on the base and divided into two groups, the flanges in each group are substantially parallel to each other, the fastening portions are arranged between the flanges and divide the flanges into several sections.

14. The case as claimed in claim 13, wherein the flanges are extended from one end of the bottom wall to the other end.

15. The case as claimed in claim 12, wherein each cover piece comprises a latching portion extended outwardly, each latching portion latches to the resisting wall.

16. The case as claimed in claim 12, wherein the bottom wall defines a bottom hole and the side walls define a plurality of side holes, the bottom hole and the side holes dispose some portions of the portable electronic device.

17. The case as claimed in claim 9, wherein the peripheral component is made of metal, plastic, or a mixture material of metal and plastic.
